(19) United States
(12) Patent Application Publication
(10) Pub. No.: US 2024/0170488 A1
(43) Pub. Date: May 23, 2024

(54) INTEGRATED CIRCUIT CELL INCLUDING COLUMN STACKED PINS

(71) Applicant: QUALCOMM Incorporated, San Diego, CA (US)

(72) Inventors: Renukprasad HIREMATH, Hillsboro, OR (US); Keyurkumar Karsanbhai KANSAGRA, Bangalore (IN); Shashikumar GANESH BHAT, Bangalore (IN); Hyeokjin LIM, San Diego, CA (US); Seung Hyuk KANG, San Diego, CA (US); Venugopal BOYNAPALLI, San Diego, CA (US); Kamesh MEDISETTI, Bangalore (IN)

(21) Appl. No.: 17/993,594

(22) Filed: Nov. 23, 2022

(51) Int. Cl. H01L 27/118; H03K 19/094

(52) U.S. Cl. CPC H01L 27/11807; H03K 19/094; H01L 2027/11866; H01L 2027/11875; H01L 2027/11881; H01L 2027/11885

(57) ABSTRACT

An integrated circuit (IC) cell including: a first logic gate comprising a first polysilicon structure and a first pin; a second logic gate comprising a second polysilicon structure and a second pin, wherein the second polysilicon structure is spaced apart and adjacent to the first polysilicon structure in a cell row direction; and a source region, common to the first and second logic gates, situated between the first and second polysilicon structures, wherein the first and second pins are on a first metal track directly over the common source region.

### FIELD

Aspects of the present disclosure relate generally to integrated circuits (ICs), and in particular, to an IC cell including column or vertically stacked pins.

### BACKGROUND

Integrated circuits (ICs), such as silicon on chips (SOCs), typically include combinational logic cells arranged in rows and columns. In designing such ICs, there is a drive to use the area or footprint of an IC in an efficient manner; for example, to make the IC smaller and/or to increase the number of IC cells for additional functionality. However, designing such ICs for improved area usage sometimes presents challenges requiring new IC cell design and layout approaches.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an integrated circuit (IC) cell. The IC cell includes a first logic gate comprising a first polysilicon structure and a first pin; a second logic gate comprising a second polysilicon structure and a second pin, wherein the second polysilicon structure is spaced apart and adjacent to the first polysilicon structure in a cell row direction; and a source region, common to the first and second logic gates, situated between the first and second polysilicon structures, wherein the first and second pins are on a first metal track directly over the common source region.

Another aspect of the disclosure relates to a method. The method includes generating a first input logic signal; generating a second input logic signal; applying the first and second logic signals to first and second pins of an integrated circuit (IC) cell, wherein the IC cell includes: a first logic gate comprising a first polysilicon structure and the first pin; a second logic gate comprising a second polysilicon structure and the second pin, wherein the second polysilicon structure is spaced apart and adjacent to the first polysilicon structure in a cell row direction; and a source region, common to the first and second logic gates, situated between the first and second polysilicon structures, wherein the first and second pins are on a first metal track directly over the common source region; receiving a first output logic signal from the IC cell, wherein the first output logic signal is based on the first input logic signal; and receiving a second output logic signal from the IC cell, wherein the second output logic signal is based on the second input logic signal.

Another aspect of the disclosure relates to a wireless communication device. The wireless communication device includes at least one antenna; a transceiver coupled to the at least one antenna; and an integrated circuit (IC) coupled to the transceiver, wherein the IC includes a set of one or more signal processing cores including an IC cell including: a first logic gate comprising a first polysilicon structure and a first pin; a second logic gate comprising a second polysilicon structure and a second pin, wherein the second polysilicon structure is spaced apart and adjacent to the first polysilicon structure in a cell row direction; and a source region, common to the first and second logic gates, situated between the first and second polysilicon structures, wherein the first and second pins are on a first metal track directly over the common source region.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1A illustrates a layout view of an example integrated circuit (IC) inverter cell in accordance with an aspect of the disclosure.

FIG. 1B illustrates a layout view of an example adjacent pair of integrated circuit (IC) inverter cells in accordance with another aspect of the disclosure.

FIG. 1C illustrates a layout view of an example multi-gate integrated circuit (IC) inverter cell in accordance with another aspect of the disclosure.

FIG. 2A illustrates a layout view of an example row of integrated circuit (IC) cell(s) in accordance with another aspect of the disclosure.

FIG. 2B illustrates a layout view of another example row of integrated circuit (IC) cell(s) in accordance with another aspect of the disclosure.

FIG. 3A illustrates a layout view of an example multi-gate integrated circuit (IC) NAND gate cell in accordance with another aspect of the disclosure.

FIG. 3B illustrates a layout view of another example multi-gate integrated circuit (IC) NAND gate cell in accordance with another aspect of the disclosure.

FIG. 4 illustrates a layout view of another example multi-gate integrated circuit (IC) NAND gate cell in accordance with another aspect of the disclosure.

FIG. 5 illustrates a layout view of another example multi-gate integrated circuit (IC) NAND gate cell in accordance with another aspect of the disclosure.

FIG. 6 illustrates a layout view of another example multi-gate integrated circuit (IC) inverter cell in accordance with another aspect of the disclosure.

FIG. 7 illustrates a flow diagram of an example method of processing signals in accordance with another aspect of the disclosure.

FIG. 8 illustrates a block diagram of an example wireless communication device in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

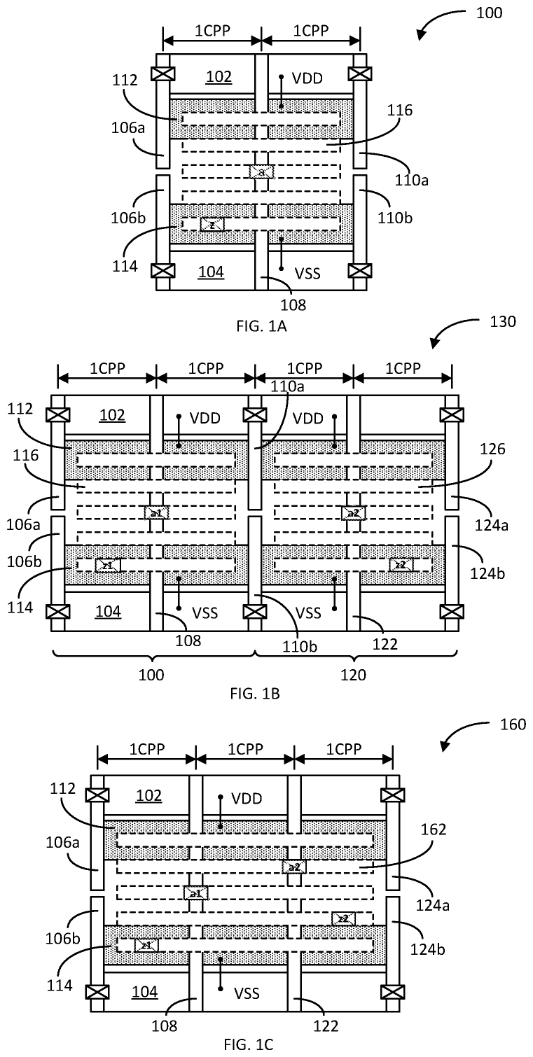

FIG. 1A illustrates a layout view of an example integrated circuit (IC) inverter cell 100 in accordance with an aspect of the disclosure. In this example, the inverter cell 100 is a single-bit cell; that is, it includes a single input pin “a” and a single output pin “z”. The inverter cell 100 is situated between a pair of horizontal power metal rails VDD 102 and VSS 104. As used herein, “horizontal” means in the cell row direction, and “vertical” means in the cell column direction.

The inverter cell 100 has a width of two (2) contacted poly pitch (CPP). That is, the inverter cell 100 includes a left upper and lower terminating polysilicon structures 106a and 106b elongated in the column or vertical direction, which may be coupled to the power rails VDD 102 and VSS 104, respectively, to provide electrical isolation for the cell from its left side. Similarly, the inverter cell 100 includes a right upper and lower terminating polysilicon structures 110a and 110b elongated in the column or vertical direction, which may also be coupled to the power rails VDD 102 and VSS 104, respectively, to provide electrical isolation for the cell from its right side. Additionally, the inverter cell 100 includes a middle polysilicon structure 108, elongated in the column or vertical direction, that serves as a gate or input for the inverter cell 100 (which may be referred to herein as a gate poly). The distance, in the row or horizontal direction, between adjacent polysilicon structures is one (1) CPP. Accordingly, as discussed, the inverter cell 100 has a width of 2 CPP: 1 CPP between polysilicon structures 106 and 108, and 1 CPP between polysilicon structures 108 and 110.

The inverter cell 100 further includes an n+ diffusion region 112 (sometimes referred to as an oxide diffusion (OD) region) upon which a p-channel metal oxide semiconductor field effect transistor (PMOS FET) is formed. The n+ diffusion region 112 is elongated in the row or horizontal direction. In this example, the region of the n+ diffusion region 112 to the right of the gate poly 108 is the source of the PMOS FET, and the region of the n+ diffusion region 112 to the left of the gate poly 108 is the drain of the PMOS FET. Similarly, the inverter cell 100 further includes a p+ diffusion region 114 upon which an n-channel metal oxide semiconductor field effect transistor (NMOS FET) is formed. The p+ diffusion region 114 is elongated in the row or horizontal direction, and spaced apart in the vertical or column direction from the n+ diffusion region 112. The region of the p+ diffusion region 114 to the right of the gate poly 108 is the source of the NMOS FET, and the region of the p+ diffusion region 114 to the left of the gate poly 108 is the drain of the NMOS FET. As the inverter cell 100 includes both PMOS and NMOS FETs, the inverter cell 100 may be referred to as a complementary metal oxide semiconductor (CMOS) inverter cell.

As schematically illustrated, the source of the PMOS FET is electrically coupled to the VDD power rail 102. Similarly, the source of the NMOS FET is electrically coupled to the VSS power rail 104. A via contact (represented herein as a square with two diagonal crisscross lines) representing input “a” is shown over and coupled to the gate poly 108. And another via contact representing the output “z” is shown over the electrically coupled drains of the PMOS and NMOS FETs (although for simplicity, the actual metal layers that electrically couple the drains of the PMOS FET and NMOS FET are not shown). For illustrative purposes, the inverter cell 100 includes a set of M0 metal layer tracks 116 elongated in the row or horizontal direction, and equally spaced part from each other in the column or vertical direction. The height of the inverter cell 100 may indicate the number of stacked M0 metal layer tracks 116 (e.g., five (5)). One or more of the set of M0 metal layer tracks 116 may provide intracell interconnects for the inverter cell 100.

FIG. 1B illustrates a layout view of an example row of integrated circuit (IC) cells 130 in accordance with another aspect of the disclosure. For descriptive purposes, the row of IC cells 130 includes two adjacent cells 100 and 120. However, it shall be understood that a row of IC cells may include many abutted or adjacent cells. Accordingly, in this example, the row of IC cells 130 includes the inverter cell 100 as previously discussed, and another inverter cell 120 adjacent to the inverter cell 100.

As depicted, the two inverter cells 100 and 120 share: the VDD and VSS power rails 102 and 104 (which may be metal layers situated above and below and extending continuously across the row of cells 130); the n+ diffusion region 112 (also continuously extending across the row of cells 130); and the p+ diffusion region 114 (also continuously extending across the row of cells 130). The two inverter cells 100 and 120 also share the upper and lower terminating polysilicon structures 110a/110b for electrically isolating the cells from each other.

The inverter cell 120 also includes a gate poly 122 and another upper and lower terminating polysilicon structures 124a and 124b. The terminating polysilicon structures 124a and 124b may be coupled to the power rails VDD 102 and VSS 104, respectively, to electrically isolate the inverter cell 120 from its right side. The inverter cell 120 also includes a PMOS FET including a source formed over the n+ diffusion region 112 to the left of the gate poly 122, and a drain formed over the n+ diffusion region 112 to the right of the gate poly 122. Similarly, the inverter cell 120 also includes an NMOS FET including a source formed over the p+ diffusion region 114 to the left of the gate poly 122, and a drain formed over the p+ diffusion region 114 to the right of the gate poly 122.

As schematically illustrated, the source of the PMOS FET of the inverter cell 120 is also electrically coupled to the VDD power rail 102. Similarly, the source of the NMOS FET of the inverter cell 120 is also electrically coupled to the VSS power rail 104. A via contact representing input “a2” is shown over and coupled to the gate poly 122 (note that via contact to the gate poly for inverter cell 100 has been relabeled as “a1” in FIG. 1B). And another via contact representing the output “z2” is shown over the electrically coupled drains of the PMOS and NMOS FETs (although for simplicity, the actual metal layers that electrically couple the drains of the PMOS FET and NMOS FET are not shown) (also note that the via contact to the drain for inverter cell 100 has been relabeled as “z1” in FIG. 1B). The inverter cells 100 and 120 are of the same height (e.g., two (2) fin height cell); and accordingly, have the same number of horizontally-aligned M0 metal layer tracks 116 and 126 (e.g., five (5)) for intracell interconnects with respect to cells 100 and 120, respectively.

Note that the cumulative width of the two adjacent inverter cells 100 and 120 is four (4) CPPs. That is, a first CPP between the terminating polysilicon structures 106a/106b and the gate poly 108 of the inverter cell 100; a second CPP between the gate poly 108 of the inverter cell 100 and the terminating polysilicon structures 110a/110b; a third CPP between the terminating polysilicon structures 110a/110b and the gate poly 122 of the inverter cell 120; and a fourth CPP between the gate poly 122 of the inverter cell 120 and the terminating polysilicon structures 124a/124b. As discussed below, a multi-gate IC cell that provides the same functionality of the two adjacent IC inverter cells but with a reduced width of three (3) CPP is described further herein.

FIG. 1C illustrates a layout view of an example multi-gate integrated circuit (IC) inverter cell 160 in accordance with another aspect of the disclosure. The term multi-gate means that the cell has more than one (1) gate (e.g., two inverters). As mentioned above, the multi-gate inverter cell 160 provides the same functionality as the two adjacent inverter cells 100 and 120 previously discussed. For descriptive purposes, the same reference numbers for similar elements in the two inverter cells 100 and 120 are used in the multi-gate inverter cell 160.

In contrast to the two adjacent inverter cells 100 and 120, the multi-gate inverter cell 160 combines the two separate source regions in the two adjacent inverter cells 100 and 120 into a common source region. For example, the two PMOS FETs share a source over the n+ diffusion region 112 to the right and left of the gate polys 108 and 122, respectively. The PMOS FETs include drains over the n+ diffusion region 112 to the left and right of the gate polys 108 and 122, respectively. Similarly, the two NMOS FETs share a source over the p+ diffusion region 114 to the right and left of the gate polys 108 and 122, respectively. The NMOS FETs include drains over the p+ diffusion region 114 to the left and right of the gate polys 108 and 122, respectively. Schematically illustrated, the common source of the PMOS FETs is coupled (electrically connected) to the VDD power rail 102, and the common source of the NMOS FETs is coupled (electrically connected) to the VSS power rail 104.

Because the PMOS FETs and the NMOS FETs share source terminals, the width of the multi-gate inverter cell 160 is three (3) CPP as compared to four (4) CPP for the two adjacent inverter cells 100 and 120. This is because the two adjacent inverter cells 100 and 120 have their own source regions. As a result, the multi-gate inverter cell 160 may be more efficient in terms of IC footprint compared to the two adjacent inverter cells 100 and 120.

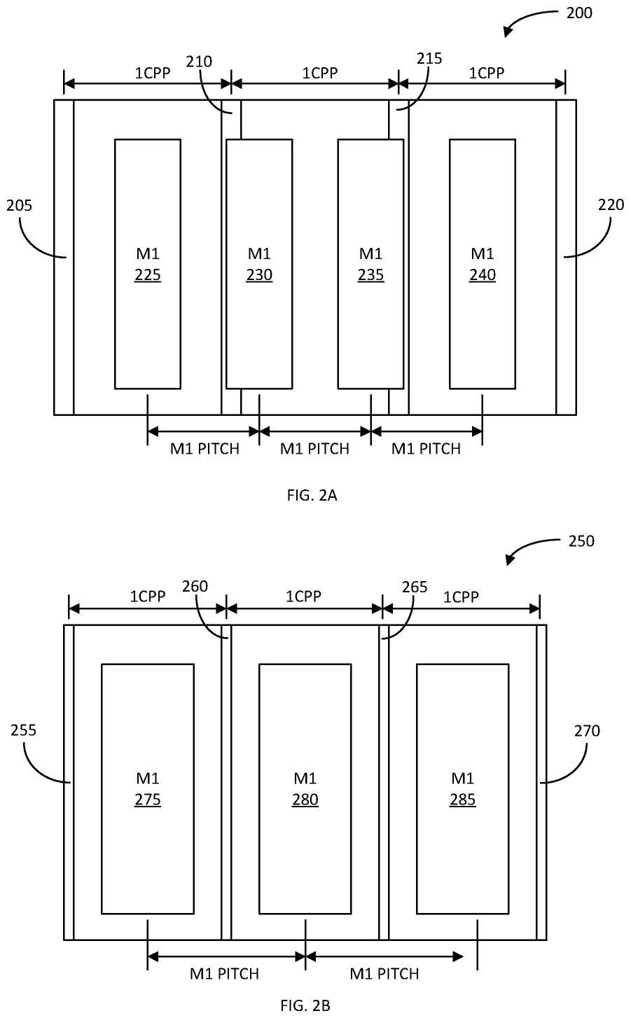

FIG. 2A illustrates a layout view of an example row of integrated circuit (IC) cell(s) 200 in accordance with another aspect of the disclosure. A place and route (PnR) IC layout tool routes to pins of an IC cell via a set of M1 metal tracks, respectively. The pins of an IC cell are the inputs and outputs of the IC cell. For example, the single inverter cell 100 has a single input pin “a” and a single output pin “z”. Similarly, the two adjacent inverter cells 100 and 120 or the multi-gate inverter cell 160 include two input pins “a1” and “a2” and two output pins “z1” and “z2”.

Similar to the polysilicon structures having a CPP, the M1 metal tracks also have an M1 pitch. For example, the row of IC cell(s) 200 includes four (4) polysilicon structures 205, 210, 215, and 220 equally spaced apart from each other by one (1) CPP. Similarly, the row of IC cell(s) 200 includes four (4) M1 tracks 225, 230, 235, and 240 equally spaced apart from each other by one (1) M1 pitch. In certain technology nodes, there may be a particular CPP/M1 pitch ratio. For instance, the row of IC cell(s) 200 has a CPP/M1 pitch ratio of 2/3. That is, for a width of 2*CPP, there are three M1 tracks. Thus, in this example, the row of IC cell(s) 200 includes four (4) M1 tracks 225, 230, 235, and 240 within four (4) polysilicon structures 205, 210, 215, and 220.

FIG. 2B illustrates a layout view of another example row of integrated circuit (IC) cell(s) 250 in accordance with another aspect of the disclosure. Other technology nodes may have a different CPP/M1 pitch ratio. For example, the row of IC cell(s) 250 includes four (4) polysilicon structures 255, 260, 265, and 270 equally spaced apart from each other by one (1) CPP. Similarly, the row of IC cell(s) 250 includes three (3) M1 tracks 275, 280, and 285 equally spaced apart from each other by one (1) M1 pitch. Accordingly, the row of IC cell(s) 250 has a CPP/M1 pitch ratio of one (1); that is, there is a one-to-one correspondence between a polysilicon structure and an M1 track. As discussed further herein, the lower CPP/M1 of the row of IC cell(s) 250 may present a problem/issue for implementing a multi-gate IC cell.

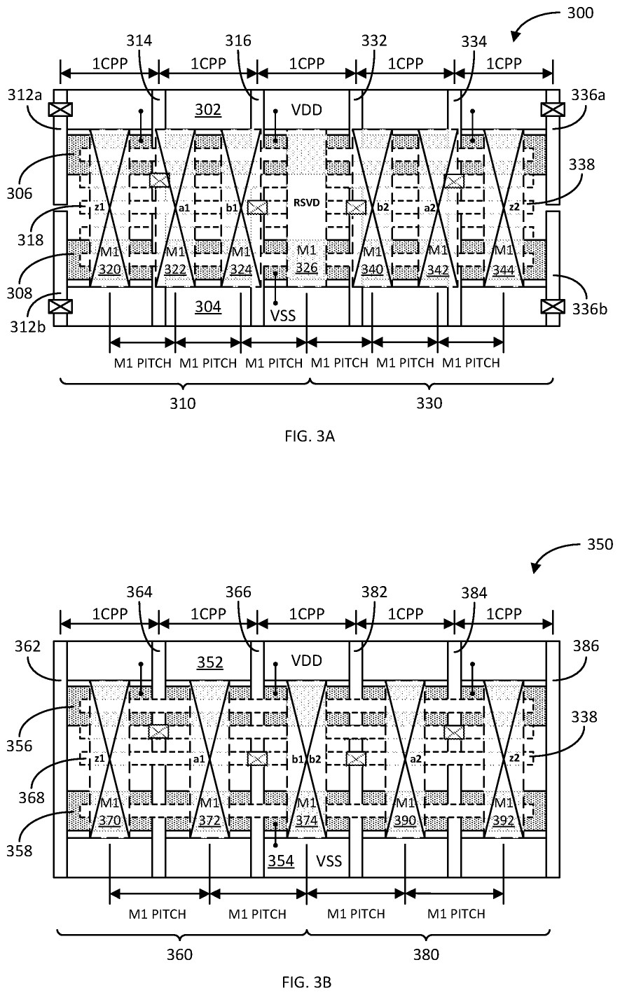

FIG. 3A illustrates a layout view of an example multi-gate integrated circuit (IC) NAND gate cell 300 in accordance with another aspect of the disclosure. As discussed in more detail herein, the multi-gate NAND gate cell 300 may be implemented in a technology node that has a CPP/M1 pitch ratio of 2/3. The multi-gate NAND gate cell 300 includes a VDD power rail 302 elongated in a cell row or horizontal direction, and a VSS power rail 304 also elongated in the cell row or horizontal direction, both span the width of the cell 300. The VDD and VSS power rails 302 and 304 are spaced apart in the cell column or vertical direction based on a height of the multi-gate NAND gate cell 300.

The multi-gate NAND gate cell 300 includes a width of five (5) CPPs, and includes cell terminating polysilicon structures 312a/312b, gate poly 314, gate poly 316, gate poly 332, gate poly 334, and terminating polysilicon structures 336a/336b, where each adjacent polysilicon structures are spaced apart by one (1) CPP. All polysilicon structures 312, 314, 316, 332, 334, and 336 are elongated in the cell column or vertical direction, and span the height of the cell 300. The two gate polys 314 and 316 pertain to a first NAND gate 310 of the multi-gate NAND gate cell 300. The other two gate polys 332 and 334 pertain to a second NAND gate 330 of the multi-gate NAND gate cell 300. The upper and lower terminating polysilicon structure 312a and 312b, which may be coupled to the VDD and VSS power rails 302 and 304, respectively, provide electrical isolation for the multi-gate NAND gate cell 300 from the left. Similarly, the upper and lower terminating polysilicon structures 336a/336b, which may also be coupled to the VDD and VSS power rails 302 and 304, respectively, provide electrical isolation for the multi-gate NAND gate cell 300 from the right.

The multi-gate NAND gate cell 300 includes an n+ diffusion region 306, over which PMOS FETs are formed, elongated and extending across the cell 300 in the cell row or horizontal direction. Similarly, the multi-gate NAND gate cell 300 includes an p+ diffusion region 308, over which NMOS FETs are formed, elongated and extending across the cell 300 in the cell row or horizontal direction. The n+ diffusion region 306 and p+ diffusion region 308 are situated between the VDD and VSS power rails 302 and 304, and spaced apart from each other based on the height of the cell 300.

As the multi-gate NAND gate cell 300 has a CPP/M1 pitch ratio of 2/3, there are seven (7) M1 metal tracks 320, 322, 324, 326, 340, 342, and 344 elongated in the cell column or vertical direction, and spaced apart from each other by one (1) M1 pitch. As previously discussed, each M1 metal track includes a pin (an input or output) of the multi-gate NAND gate cell 300.

For example, M1 metal track 320 includes a pin “z1” for an output of the first NAND gate 310; M1 metal track 322 includes a pin “a1” for a first input of the first NAND gate 310; M1 metal track 324 includes a pin “b1” for a second input of the first NAND gate 310; M1 metal track 340 includes a pin “b2” for a second input of the second NAND gate 330; M1 metal track 342 includes a pin “a2” for a first input of the second NAND gate 330; and M1 metal track 344 includes a pin “z2” for an output of the second NAND gate 330. Note that because there are seven (7) M1 tracks in the multi-gate NAND gate cell 300, and there are six (6) input/output pins, the extra M1 track 326 may be reserved for the PnR tool to use for routing through the cell 300 and/or other purpose.

A two-input NAND gate includes two parallel PMOS FETs coupled between the VDD power rail 302 and an output of the NAND gate, and two series NMOS FETs coupled between the output and the VSS power rail 304. With regard to the first NAND gate 310, the first PMOS FET includes a source formed over the n+ diffusion region 306 to the left of gate poly 314, the second PMOS FET includes a source formed over the n+ diffusion region 306 to the right of gate poly 316, and the first and second PMOS FETs share a drain over the n+ diffusion region 306 between the gate polys 314 and 316. The first NMOS FET includes a drain formed over the p+ diffusion region 308 to the left of gate poly 314, and a source formed over the p+ diffusion region 308 to the right of gate poly 314. The second NMOS FET includes a drain formed over the p+ diffusion region 308 to the left of gate poly 316 (shared with the source of the first NMOS FET), and a source formed over the p+ diffusion region 308 to the right of gate poly 316.

The first NAND gate 310 includes a set of M0 metal tracks 318 (intracell interconnects), elongated in the cell row or horizontal direction and equally spaced apart from each other in the cell column or vertical direction, and electrically coupling the M1 metal track 322 including input pin “a1” to the gate poly 314 (represented as a via contact over the gate poly 314), electrically coupling the M1 metal track 324 including input pin “b1” to the gate poly 316 (represented as a via contact over the gate poly 316), and electrically coupling the M1 metal track 320 including output pin “z1” to the drains of the first and second PMOS FETs and the first NMOS FET of the first NAND gate 310.

With regard to the second NAND gate 330, the first PMOS FET includes a source formed over the n+ diffusion region 306 to the right of gate poly 334, the second PMOS FET includes a source formed over the n+ diffusion region 306 to the left of gate poly 332, and the first and second PMOS FETs share a drain over the n+ diffusion region 306 between the gate polys 332 and 334. The first NMOS FET includes a drain formed over the p+ diffusion region 308 to the right of gate poly 334, and a source formed over the p+ diffusion region 308 to the left of gate poly 334. The second NMOS FET includes a drain formed over the p+ diffusion region 308 to the right of gate poly 332 (shared with the source of the first NMOS FET), and a source formed over the p+ diffusion region 308 to the left of gate poly 332.

The second NAND gate 330 includes a set of M0 metal tracks 338 (intracell interconnects), elongated in the cell row or horizontal direction and equally spaced apart from each other in the cell column or vertical direction, electrically coupling the M1 metal track 342 including input pin “a2” to the gate poly 334 (represented as a via contact over the gate poly 334), electrically coupling the M1 metal track 340 including input pin “b2” to the gate poly 332 (represented as a via contact over the gate poly 332), and electrically coupling the M1 metal track 344 including output pin “z2” to the common drains of the first and second PMOS FETs and first NMOS FET of the second NAND gate 330.

As illustrated, in this technology node where the CPP/M1 ratio is 2/3, the multi-gate NAND gate cell 300 may be implemented because there are equal or more M1 tracks for pins of the cell. For example, the multi-gate NAND gate cell 300 includes seven (7) M1 tracks, which is more than the six (6) pins for the cell. As discussed further herein, in other technology node where the CPP/M1 ratio is greater than 2/3, such as one (1), the number of available M1 metal tracks may be less than the number of pins for the cell. In such case, a multi-gate cell in the configuration of cell 300 may not be implemented because there are not enough M1 metal tracks to accommodate the pins for the cell.

FIG. 3B illustrates a layout view of an example multi-gate integrated circuit (IC) NAND gate cell 350 in accordance with another aspect of the disclosure. As discussed in more detail herein, the multi-gate NAND gate cell 350 may be implemented in a technology node that has a CPP/M1 pitch ratio of one (1). The multi-gate NAND gate cell 350 includes a VDD power rail 352 elongated in a cell row or horizontal direction, and a VSS power rail 354 also elongated in the cell row or horizontal direction, both span the width of the cell 350. The VDD and VSS power rails 352 and 354 are spaced apart in the cell column or vertical direction based on a height of the multi-gate NAND gate cell 350.

The multi-gate NAND gate cell 350 includes a width of five (5) CPPs, and includes cell terminating polysilicon structure 362, gate poly 364, gate poly 366, gate poly 382, gate poly 384, and terminating polysilicon structure 386, where each adjacent polysilicon structures are spaced apart by one (1) CPP. All polysilicon structures 362, 364, 366, 382, 384, and 386 are elongated in the cell column or vertical direction, and span the height of the cell. The two gate polys 364 and 366 pertain to a first NAND gate 360 of the multi-gate NAND gate cell 350. The other two gate polys 382 and 384 pertain to a second NAND gate 380 of the multi-gate NAND gate cell 350. The terminating polysilicon structure 362, which may be floating, provides electrical isolation for the multi-gate NAND gate cell 350 from the left. Similarly, the terminating polysilicon structure 386, which may also be floating, provides electrical isolation for the multi-gate NAND gate cell 350 from the right.

The multi-gate NAND gate cell 350 includes an n+ diffusion region 356, over which PMOS FETs are formed, elongated and extending across the cell 350 in the cell row or horizontal direction. Similarly, the multi-gate NAND gate cell 350 includes an p+ diffusion region 358, over which NMOS FETs are formed, elongated and extending across the cell 350 in the cell row or horizontal direction. The n+ diffusion region 356 and p+ diffusion region 358 are situated between the VDD and VSS power rails 352 and 354, and spaced apart from each other based on the height of the cell 350.

As the multi-gate NAND gate cell 350 has a CPP/M1 pitch ratio of one (1), there are five (5) M1 metal tracks 370, 372, 374, 390, and 392 elongated in the cell column or vertical direction, and spaced apart from each adjacent track by one (1) M1 pitch. As previously discussed, each M1 metal track includes a pin (an input or output) of the multi-gate NAND gate cell 350. However, the multi-gate NAND gate cell 350 has a problem because there are only five (5) M1 metal tracks, and the multi-gate NAND gate cell 350 requires six (6) pins. For illustrative purposes, the M1 metal track 374 depicts the pin conflict by being labeled as “b1/b2”. Accordingly, the multi-gate NAND gate cell 350 does not have enough M1 metal tracks to accommodate the required pins.

For instance, M1 metal track 370 includes a pin “z1” for an output of the first NAND gate 360; M1 metal track 372 includes a pin “a1” for a first input of the first NAND gate 360; M1 metal track 390 includes a pin “a2” for a first input of the second NAND gate 380; and M1 metal track 392 includes a pin “z2” for an output of the second NAND gate 330. However, there are still two more pins for input “b1” for the first NAND gate 360 and input “b2” for the second NAND gate 380, but only one remaining M1 metal track 374. Thus, another multi-gate cell design and layout approach is needed to implement the multi-gate NAND gate cell with a CPP/M1 pitch ratio of one (1).

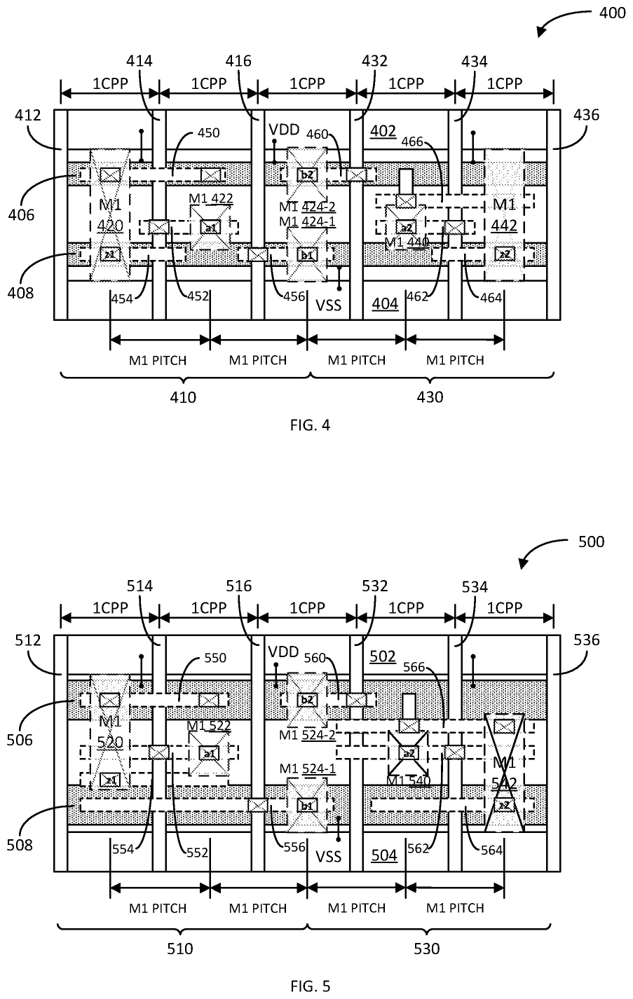

FIG. 4 illustrates a layout view of another example multi-gate integrated circuit (IC) NAND gate cell 400 in accordance with another aspect of the disclosure. As discussed in more detail herein, the multi-gate NAND gate cell 400 may be implemented in a technology node that has a CPP/M1 pitch ratio of one (1). The multi-gate NAND gate cell 400 includes a VDD power rail 402 elongated in a cell row or horizontal direction, and a VSS power rail 404 also elongated in the cell row or horizontal direction, both span the width of the cell 400. The VDD and VSS power rails 402 and 404 are spaced apart in the cell column or vertical direction based on a height of the multi-gate NAND gate cell 400.

The multi-gate NAND gate cell 400 includes a width of five (5) CPPs, and includes cell terminating polysilicon structure 412, gate poly 414, gate poly 416, gate poly 432, gate poly 434, and terminating polysilicon structure 436, where each adjacent polysilicon structures are spaced apart by one (1) CPP. All polysilicon structures 412, 414, 416, 432, 434, and 436 are elongated in the cell column or vertical direction, and span the height of the cell. The two gate polys 414 and 416 pertain to a first NAND gate 410 of the multi-gate NAND gate cell 400. The other two gate polys 432 and 434 pertain to a second NAND gate 430 of the multi-gate NAND gate cell 400. The terminating polysilicon structure 412, which may be floating, provides electrical isolation for the multi-gate NAND gate cell 400 from the left. Similarly, the terminating polysilicon structure 436, which may also be floating, provides electrical isolation for the multi-gate NAND gate cell 400 from the right.

The multi-gate NAND gate cell 400 includes an n+ diffusion region 406, over which PMOS FETs are formed, elongated and extending across the cell 400 in the cell row or horizontal direction. Similarly, the multi-gate NAND gate cell 400 includes an p+ diffusion region 408, over which NMOS FETs are formed, elongated and extending across the cell 400 in the cell row or horizontal direction. The n+ diffusion region 406 and p+ diffusion region 408 are situated between the VDD and VSS power rails 402 and 404, and spaced apart from each other based on the height of the cell 400.

As the multi-gate NAND gate cell 400 has a CPP/M1 pitch ratio of one (1), there are five (5) M1 metal tracks 420, 422, a two-pin, column- or vertically-stacked, M1 metal track 424-1 and 424-2, 440, and 442 spaced apart from each adjacent track by one (1) M1 pitch. As previously discussed, each M1 metal track includes a pin (an input or output) of the multi-gate NAND gate cell 400. However, in contrast to the multi-gate NAND gate cell 350, the two-pin, column- or vertically-stacked, metal track 424-1 and 424-2, in addition to the other M1 metal tracks 420, 422, 440, and 442, accommodate the six (6) pins for the multi-gate NAND gate cell 400.

For example, M1 metal track 420 includes a pin “z1” for an output of the first NAND gate 410; M1 metal track 422 includes a pin “a1” for a first input of the first NAND gate 410; first column- or vertically stacked M1 track 424-1 includes a pin “b1” for a second input of the first NAND gate 410; second column- or vertically stacked M1 track 424-2 includes a pin “b2” for a second input of the second NAND gate 430; M1 metal track 440 includes a pin “a2” for a first input of the second NAND gate 430; and M1 metal track 442 includes a pin “z2” for an output of the second NAND gate 430.

As previously discussed, a two-input NAND gate includes two parallel PMOS FETs coupled between the VDD power rail 402 and an output of the NAND gate, and two series NMOS FETs coupled in series between the output and the VSS power rail 404. With regard to the first NAND gate 410, the first PMOS FET includes a source formed over the n+ diffusion region 406 to the left of gate poly 414, the second PMOS FET includes a source formed over the n+ diffusion region 406 to the right of gate poly 416, and the first and second PMOS FETs share a drain over the n+ diffusion region 406 between the gate polys 414 and 416. The first NAND gate 410 includes a set of M0 metal tracks 450, 452, and 454/456 (intracell interconnects) elongated in the cell row or horizontal direction and equally spaced apart from each other in the cell column or vertical direction (although the one between tracks 450 and 452 is not shown or may not be used). The M0 track 450 electrically couples the common drain of the PMOS FETs to the M1 metal track 420 including output pin “z1”; the M0 track 452 electrically couples the gate poly 414 (represented as a via contact over the gate poly 414) to the M1 metal track 422 including input pin “a1”; the M0 track 454 electrically couples the drain of the first NMOS FET to the M1 track 420; and the M0 track 456 electrically couples the gate poly 416 (represented as a via contact over the gate poly 416) to the first column- or vertically stacked M1 metal track 424-1 including input pin “b1”.

With regard to the second NAND gate 430, the first PMOS FET includes a source formed over the n+ diffusion region 406 to the right of gate poly 434, the second PMOS FET includes a source formed over the n+ diffusion region 406 to the left of gate poly 432, and the first and second PMOS FETs share a drain over the n+ diffusion region 406 between the gate polys 432 and 434. The second NAND gate 430 includes a set of M0 metal tracks 460, 462, 464, and 466 (intracell interconnects) elongated in the cell row or horizontal direction and equally spaced apart from each other in the cell column or vertical direction. The M0 track 460 electrically couples the gate poly 432 (represented as a via contact over the gate poly 432) to the second column- or vertically stacked M1 metal track 424-2 including input pin “b2”; the M0 track 462 electrically couples the gate poly 434 (represented as a via contact over the gate poly 434) to the M1 metal track 440 including input pin “a2”; the M0 track 464 electrically couples the drain of the first NMOS FET to the M1 track 442; and the M0 track 466 electrically couple the common drains of the PMOS FETs to the M1 track 442 including the output pin “z2”.

Thus, the column- or vertically-stacked M1 metal track 424-1 and 424-2 (situated between gate polys 416 and 432) provide the extra pin to meet the number of pins required for the multi-gate cell 400. Further, the column- or vertically-stacked M1 metal tracks 424-1 and 424-2 including the pins “b1” and “b2” are situated over the common source region shared by the two NAND gates 410 and 430 (e.g., generally, logic gates), respectively. Additionally, the input pins “b1” and “b2” of the column- or vertically-stacked M1 metal track 424-1 and 424-2 are situated over the p+ and n+ diffusion regions 408 and 406, respectively (note that the other input pins “a1” and “a2” are situated in the cell region between the diffusion regions 406 and 408). Moreover, the M0 metal tracks 456 and 460 used to electrically couple the input pins “b1” and “b2” to the corresponding gate polys 416 and 432 may be the closest to the corresponding VSS and VDD power rails 404 and 402, respectively. Although NAND gates 410 and 430 are used to exemplify the column- or vertically-stacked multi-pin M1 metal track layout concept herein, it shall be understood that the multi-gate cell 400 may be implemented with any two (same or different) logic gates sharing a common source region coupled to VDD and VSS power rails.

FIG. 5 illustrates a layout view of another example multi-gate integrated circuit (IC) two-input NAND gate cell 500 in accordance with another aspect of the disclosure. The multi-gate IC NAND gate cell 500 is a variation of multi-gate IC NAND gate cell 400, and includes many same/similar elements as indicated by the same reference numbers but with the most significant digit being a “5” in multi-gate IC NAND gate cell 500 instead of a “4” in multi-gate IC NAND gate cell 400.

A difference between multi-gate IC NAND gate cells 400 and 500 is that multi-gate IC NAND gate cell 500 has a height greater than the height of multi-gate IC NAND gate cells 400. For example, the multi-gate NAND gate cell 400 may be a single-fin height cell, whereas the multi-gate NAND gate cell 500 may be a two-fin height cell. In this example, the greater height of multi-gate NAND gate cells 500 accommodates five (5) M0 metal tracks compared to four (4) in multi-gate NAND gate cells 400. Nonetheless, the attributes discussed above with respect to multi-gate NAND gate 500 apply to multi-gate NAND gate 400.

That is, the multi-gate IC NAND gate 500 includes column- or vertically-stacked two-pin M1 metal track 524-1 and 524-2 (situated between gate polys 516 and 532) provide the extra pin to meet the required pins for the multi-gate cell 500. Further, the column- or vertically-stacked M1 metal track 524-1 and 524-2 including the pins “b1” and “b2” are situated over the common source region shared by the two NAND gates 510 and 530 (e.g., generally, logic gates), respectively. Additionally, the input pins “b1” and “b2” of the column- or vertically-stacked M1 metal track 524-1 and 524-2 are situated over the p+ and n+ diffusion regions 508 and 506, respectively (whereas the other input pins “a1” and “a2” are situated in the cell region between the diffusion regions 406 and 408). Moreover, the M0 metal tracks 556 and 560 used to electrically couple the input pins “b1” and “b2” to the corresponding gate polys 516 and 532 may be the closest to the corresponding VSS and VDD power rails 504 and 502, respectively. Although NAND gates 510 and 530 are used to exemplify the column- or vertically-stacked multi-pin M1 metal track layout concept herein, it shall be understood that the multi-gate cell 500 may be implemented with any two (same or different) logic gates sharing a common source region coupled to VDD and VSS power rails.

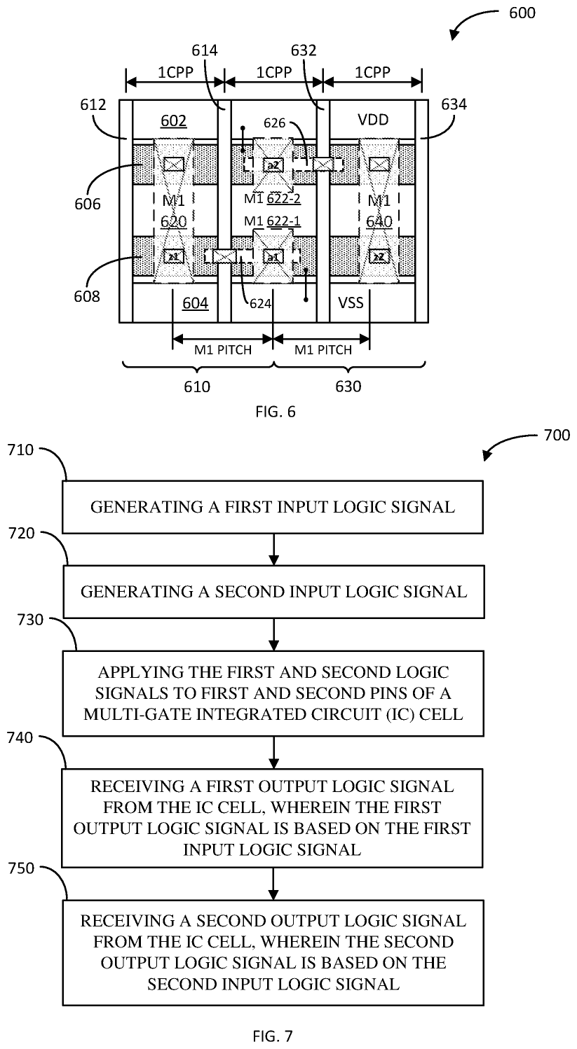

FIG. 6 illustrates a layout view of another example multi-gate integrated circuit (IC) inverter cell 600 in accordance with another aspect of the disclosure. As discussed in more detail herein, the multi-gate inverter cell 600 may be implemented in a technology node that has a CPP/M1 pitch ratio of one (1). The multi-gate inverter cell 600 includes a VDD power rail 602 elongated in a cell row or horizontal direction, and a VSS power rail 604 elongated in the cell row or horizontal direction, both span the width of the cell 600. The VDD and VSS power rails 602 and 604 are spaced apart in the cell column or vertical direction based on a height of the multi-gate inverter cell 600.

The multi-gate inverter cell 600 includes a width of three (3) CPPs, and includes cell terminating polysilicon structure 612, gate poly 614, gate poly 632, and terminating polysilicon structure 634, where each adjacent polysilicon structures are spaced apart by one (1) CPP. All polysilicon structures 612, 614, 632, and 634 are elongated in the cell column or vertical direction, and span the height of the cell 600. The gate poly 614 pertains to a first inverter 610 of the multi-gate inverter cell 600. The other gate poly 632 pertains to a second inverter cell 630 of the multi-gate inverter cell 600. The terminating polysilicon structure 612, which may be floating, provides electrical isolation for the multi-gate inverter cell 600 from the left. Similarly, the terminating polysilicon structure 634, which may also be floating, provides electrical isolation for the multi-gate inverter cell 600 from the right.

The multi-gate inverter cell 600 includes an n+ diffusion region 606, over which PMOS FETs are formed, elongated and extending across the cell 600 in the cell row or horizontal direction. Similarly, the multi-gate inverter cell 600 includes an p+ diffusion region 608, over which NMOS FETs are formed, elongated and extending across the cell 600 in the cell row or horizontal direction. The n+ diffusion region 606 and p+ diffusion region 608 are situated between the VDD and VSS power rails 602 and 604, and spaced apart from each other based on the height of the cell 600.

As the multi-gate inverter cell 600 has a CPP/M1 pitch ratio of one (1), there are three (3) M1 metal tracks: M1 track 620, column- or vertically-stacked two-pin M1 metal track 622-1 and 622-2, and M1 track 640 spaced apart from each adjacent track by one (1) M1 pitch. As previously discussed, each M1 metal track includes a pin (an input or output) of the multi-gate inverter cell 600. The column- or vertically-stacked two-pin M1 metal track 622-1 and 622-2, in addition to the other M1 metal tracks 620 and 640, accommodate the four (4) pins for the multi-gate inverter cell 600.

For example, M1 metal track 620 includes a pin “z1” for an output of the first inverter 610; first column- or vertically stacked M1 track 622-1 includes a pin “a1” for an input of the first inverter 610; second column- or vertically stacked M1 track 622-2 includes a pin “a2” for an input of the second inverter 630; and M1 metal track 640 includes a pin “z2” for an output of the second inverter 630.

With regard to the first inverter 610, the PMOS FET includes a source situated over the n+ diffusion region 606 to the right of gate poly 614, and a drain over the n+ diffusion region 606 to the left of gate poly 614. The NMOS FET of the first inverter 610 includes a source situated over the p+ diffusion region 608 to the right of gate poly 614, and a drain situated over the p+ diffusion region 608 to the left of gate poly 614. Similarly, with regard to the second inverter 630, the PMOS FET includes a source situated over the n+ diffusion region 606 to the left of gate poly 632, and a drain over the n+ diffusion region 606 to the right of gate poly 632. The NMOS FET of the second inverter 630 includes a source situated over the p+ diffusion region 608 to the left of gate poly 632, and a drain situated over the p+ diffusion region 608 to the right of gate poly 632.

Thus, the column- or vertically-stacked two-pin M1 metal track 622-1 and 622-2 (situated between gate polys 614 and 632) provide the extra pin to meet the number of pins required for the multi-gate inverter cell 600. Further, the column- or vertically-stacked two-pin M1 metal track 622-1 and 622-2 including the pins “a1” and “a2” are situated over the common source region shared by the two inverters 610 and 630 (e.g., generally, logic gates), respectively. Additionally, the input pins “a1” and “a2” of the column- or vertically-stacked M1 metal track 622-1 and 622-2 are situated over the p+ and n+ diffusion regions 608 and 606, respectively. Moreover, the M0 metal tracks 624 and 626 electrically coupling the input pins “a1” and “a2” to the corresponding gate polys 614 and 632 may be the closest to the corresponding VSS and VDD power rails 604 and 602, respectively. Although inverters 610 and 630 are used to exemplify the column- or vertically-stacked multi-pin M1 metal track layout concept herein, it shall be understood that the multi-gate cell 600 may be implemented with any two (same or different) logic gates sharing a common source region coupled to VDD and VSS power rails.

FIG. 7 illustrates a flow diagram of an example method 700 of processing signals in accordance with another aspect of the disclosure. The method 700 includes generating a first input logic signal (block 710). The first input logic signal may be generated by an integrated circuit (IC) cell of an IC. The method 700 further includes generating a second input logic signal (block 720). Similarly, the second input logic signal may be generated by another IC cell of the IC.

Additionally, the method 700 includes applying the first and second logic signals to column- or vertically-stacked first and second pins of a multi-gate IC cell (block 730). As previously discussed, the column- or vertically-stacked first and second pins of the multi-gate IC cell may be situated in a VDD and VSS coupled-common source region common for the logic gates of the multi-gate IC cell. Thus, applying the first and second logic signals to the multi-gate IC cell may include routing the signals to pins “b1” and “b2” of multi-gate NAND gate cell 400 or 500, or pins “a1” and “a2” of multi-gate inverter cell 600, respectively.

The method 700 includes receiving a first output logic signal from the multi-gate cell, wherein the first output logic signal is based on the first input logic signal (block 740). For example, an IC cell of the IC may receive the first output logic signal produced at pin “z1” of multi-gate NAND gate cell 400 or 500, or multi-gate inverter cell 600. Additionally, the method 700 includes receiving a second output logic signal from the multi-gate cell, wherein the second output logic signal is based on the second input logic signal (block 750). For example, an IC cell of the IC may receive the second output logic signal produced at pin “z2” of multi-gate NAND gate cell 400 or 500, or multi-gate inverter cell 600.

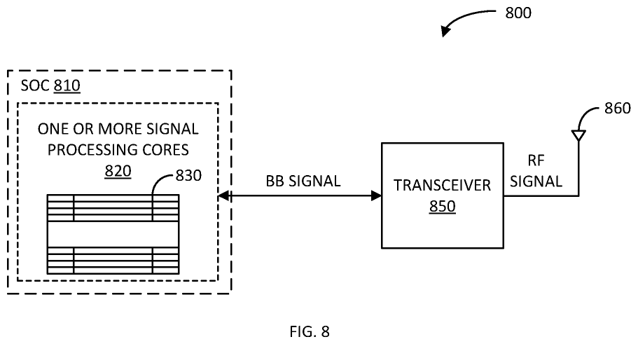

FIG. 8 illustrates a block diagram of an example wireless communication device 800 in accordance with another aspect of the disclosure. The wireless communication device 800 may be a smart phone, a desktop computer, laptop computer, tablet device, Internet of Things (IoT), wearable wireless device (e.g., wireless watch), and other types of wireless device.

In particular, the wireless communication device 800 includes an integrated circuit (IC), which may be implemented as a system on chip (SOC) 810. The SOC 810 includes one or more signal processing cores 820, which may be implemented with a two-dimensional array of IC cells 830. One or more of the IC cells 830 may be implemented as a multi-gate IC cell with column or vertical stacked pins in a VDD/VSS coupled-common source region, as exemplified in multi-gate IC cells 400, 500, and 600 previously discussed. The one or more signal processing cores 820 may be configured to generate a transmit baseband (BB) signal and process a received baseband (BB) signal.

The wireless communication device 800 may further include a transceiver 850 and at least one antenna 860 (e.g., an antenna array). The transceiver 850 is coupled to the one or more signal processing cores 820 to receive therefrom the transmit BB signal and provide thereto the received BB signal. The transceiver 850 is configured to convert the transmit BB signal into a transmit radio frequency (RF) signal, and convert a received RF signal into the received BB signal. The transceiver 850 is coupled to the at least one antenna 860 to provide thereto the transmit RF signal for electromagnetic radiation into a wireless medium for wireless transmission, and receive the received RF signal electromagnetically picked up from the wireless medium by the at least one antenna 860.

The following provides an overview of aspects of the present disclosure:

Aspect 1: An integrated circuit (IC) cell, comprising: a first logic gate comprising a first polysilicon structure and a first pin; a second logic gate comprising a second polysilicon structure and a second pin, wherein the second polysilicon structure is spaced apart and adjacent to the first polysilicon structure in a cell row direction; and a source region, common to the first and second logic gates, situated between the first and second polysilicon structures, wherein the first and second pins are on a first metal track directly over the common source region.

Aspect 2: The IC cell of aspect 1, wherein the first metal track is on an M1 metal layer.

Aspect 3: The IC cell of aspect 1 or 2, wherein the first and second pins comprise input pins, respectively.

Aspect 4: The IC cell of any one of aspects 1 to 3, further comprising: a first power rail; a first diffusion region electrically connected to the first power rail at the common source region; a second power rail; and a second diffusion region electrically connected to the second power rail at the common source region.

Aspect 5: The IC cell of aspect 4, wherein the first pin is situated directly over the first diffusion region, and the second pin is situated directly over the second diffusion region.

Aspect 6: The IC cell of aspect 5, further comprising first and second intracell interconnects electrically coupling the first and second pins to the first and second polysilicon structures, respectively.

Aspect 7: The IC cell of aspect 6, wherein the first and second intracell interconnects are situated directly over the first and second diffusion regions, respectively.

Aspect 8: The IC cell of aspect 6 or 7, wherein the first and second intercell interconnects are on an M0 metal layer.

Aspect 9: The IC cell of any one of aspects 6 to 8, further comprising a set of intracell interconnects including the first and second intracell interconnects, wherein each intracell interconnect is elongated in the cell row direction and spaced apart from each other in a cell column direction, and wherein the first and second intracell interconnects among the set of intracell interconnects are situated closest to the first and second power rails, respectively.

Aspect 10: The IC cell of any one of aspects 1-9, wherein the first logic gate comprises: a first p-channel metal oxide semiconductor field effect transistor (PMOS FET), wherein the first polysilicon structure serves as a first gate for the first PMOS FET, wherein the first PMOS FET includes a first source situated over an n+ diffusion region within the common source region; and a first n-channel metal oxide semiconductor field effect transistor (NMOS FET), wherein the first polysilicon structure serves as a first gate for the first NMOS FET, wherein the first NMOS FET includes a first source situated over a p+ diffusion region within the common source region.

Aspect 11: The IC cell of aspect 10, wherein the second logic gate comprises: a second PMOS FET, wherein the second gate polysilicon gate structure serves as a second gate for the second PMOS FET, and wherein the second PMOS FET shares the first source with the first PMOS FET; and a second NMOS FET, wherein the second gate polysilicon gate structure serves as a second gate for the second NMOS FET, and wherein the second NMOS FET shares the first source with the first NMOS FET.

Aspect 12: The IC cell of aspect 11, further comprising: a third polysilicon structure spaced apart and adjacent to the first polysilicon structure in the cell row direction; and a fourth polysilicon structure spaced apart and adjacent to the second polysilicon structure in the cell row direction.

Aspect 13: The IC cell of aspect 12, wherein: the first PMOS FET includes a first drain situated over the n+ diffusion region between the first and third polysilicon structures; the first NMOS FET includes a first drain situated over the p+ diffusion region between the first and third polysilicon structures; the second PMOS FET includes a second drain situated over the n+ diffusion region between the second and fourth polysilicon structures; and the second NMOS FET includes a second drain situated over the p+ diffusion region between the second and fourth polysilicon structures.

Aspect 14: The IC cell of aspect 13, wherein: the first logic gate includes a third pin on a second metal track situated between the first gate polysilicon structure and the first polysilicon structure; and the second logic gate includes a fourth pin on a third metal track situated between the second gate polysilicon structure and the second polysilicon structure.

Aspect 15: The IC cell of claim 14, wherein each adjacent pair of the first, second, third, and fourth polysilicon structures is separated by a first pitch, wherein each adjacent pair of the first, second, and third metal tracks is separated by a second pitch, and wherein a ratio of the first pitch to the second pitch is one (1).

Aspect 16: The IC cell of aspect 14, wherein the third and fourth pins comprise output pins, respectively.

Aspect 17: The IC cell of aspect 16, wherein the first and second polysilicon gate structures comprise cell terminating polysilicon gate structures.

Aspect 18: The IC cell of aspect 14, wherein: the third pin is electrically coupled to the respective first drains of the first PMOS and NMOS FETs; and the fourth pin is electrically coupled to the respective second drains of the second PMOS and NMOS FETs.

Aspect 19: The IC cell of aspect 14, wherein the third and fourth pins are situated between the n+ and p+ diffusion regions.

Aspect 20: The IC cell of aspect 20, wherein the third and fourth pins comprise input pins, respectively.

Aspect 21: The IC cell of aspect 14, further comprising: a first intracell interconnect electrically coupling the third pin to the third polysilicon structure; and a second intracell interconnect electrically coupling the fourth pin to the fourth polysilicon structure.

Aspect 22: The IC cell of aspect 21, wherein the first and second intracell interconnects are on an M0 metal layer.

Aspect 23: The IC cell of aspect 20, wherein the first logic gate comprises: a third PMOS FET, wherein the third polysilicon structure serves as a third gate for the third PMOS FET, and wherein the third PMOS FET includes a third drain coupled to the first drain of the first PMOS FET; and a third NMOS FET, wherein the third polysilicon structure serves as a third gate for the third NMOS FET, and wherein the third NMOS FET includes a third source coupled to the first drain of the first NMOS FET.

Aspect 24: The IC cell of claim 23, wherein the second logic gate comprises: a fourth PMOS FET, wherein the fourth polysilicon structure serves as a fourth gate for the fourth PMOS FET, and wherein the fourth PMOS FET includes a fourth drain coupled to the second drain of the second PMOS FET; and a fourth NMOS FET, wherein the fourth polysilicon structure serves as a fourth gate for the fourth NMOS FET, and wherein the fourth NMOS FET includes a fourth source coupled to the second drain of the second NMOS FET.

Aspect 25: The IC cell of aspect 14, further comprising: a fifth polysilicon structure spaced apart and adjacent to the third polysilicon structure in the cell row direction; and a sixth polysilicon structure spaced apart and adjacent to the fourth polysilicon structure in the cell row direction.

Aspect 26: The IC cell of aspect 25, wherein: the first logic gate includes a fifth pin on a fourth metal track situated between the third and fifth polysilicon structures; and the second logic gate includes a sixth pin on a fifth metal track situated between the fourth and sixth polysilicon structures.

Aspect 27: The IC cell of aspect 26, wherein the fifth and sixth pins comprise output pins, respectively.

Aspect 28: The IC cell of any one of aspects 25-27, wherein the fifth and sixth polysilicon structures are cell terminating polysilicon structures, respectively.

Aspect 29: A method, comprising: generating a first input logic signal; generating a second input logic signal; applying the first and second logic signals to first and second pins of an integrated circuit (IC) cell, wherein the IC cell includes: a first logic gate comprising a first polysilicon structure and the first pin; a second logic gate comprising a second polysilicon structure and the second pin, wherein the second polysilicon structure is spaced apart and adjacent to the first polysilicon structure in a cell row direction; and a source region, common to the first and second logic gates, situated between the first and second polysilicon structures, wherein the first and second pins are on a first metal track directly over the common source region; receiving a first output logic signal from the IC cell, wherein the first output logic signal is based on the first input logic signal; and receiving a second output logic signal from the IC cell, wherein the second output logic signal is based on the second input logic signal.

Aspect 30: An wireless communication device, comprising: at least one antenna; a transceiver coupled to the at least one antenna; and an integrated circuit (IC) coupled to the transceiver, wherein the IC includes a set of one or more signal processing cores including an IC cell comprising:: a first logic gate comprising a first polysilicon structure and a first pin; a second logic gate comprising a second polysilicon structure and a second pin, wherein the second polysilicon structure is spaced apart and adjacent to the first polysilicon structure in a cell row direction; and a source region, common to the first and second logic gates, situated between the first and second polysilicon structures, wherein the first and second pins are on a first metal track directly over the common source region.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An integrated circuit (IC) cell, comprising:
a first logic gate comprising a first polysilicon structure and a first pin;
a second logic gate comprising a second polysilicon structure and a second pin, wherein the second polysilicon structure is spaced apart and adjacent to the first polysilicon structure in a cell row direction; and
a source region, common to the first and second logic gates, situated between the first and second polysilicon structures, wherein the first and second pins are on a first metal track directly over the common source region.

2. The IC cell of claim 1, wherein the first metal track is on an M1 metal layer.

3. The IC cell of claim 1, wherein the first and second pins comprise input pins, respectively.

4. The IC cell of claim 1, further comprising:
a first power rail;
a first diffusion region electrically connected to the first power rail at the common source region;
a second power rail; and
a second diffusion region electrically connected to the second power rail at the common source region.

5. The IC cell of claim 4, wherein the first pin is situated directly over the first diffusion region, and the second pin is situated directly over the second diffusion region.

6. The IC cell of claim 5, further comprising first and second intracell interconnects electrically coupling the first and second pins to the first and second polysilicon structures, respectively.

7. The IC cell of claim 6, wherein the first and second intracell interconnects are situated directly over the first and second diffusion regions, respectively.

8. The IC cell of claim 6, wherein the first and second intracell interconnects are on an M0 metal layer.

9. The IC cell of claim 6, further comprising a set of intracell interconnects including the first and second intracell interconnects, wherein each intracell interconnect is elongated in the cell row direction and spaced apart from each other in a cell column direction, and wherein the first and second intracell interconnects among the set of intracell interconnects are situated closest to the first and second power rails, respectively.

10. The IC cell of claim 1, wherein the first logic gate comprises:
a first p-channel metal oxide semiconductor field effect transistor (PMOS FET), wherein the first polysilicon structure serves as a first gate for the first PMOS FET, and wherein the first PMOS FET includes a first source situated over an n+ diffusion region within the common source region; and
a first n-channel metal oxide semiconductor field effect transistor (NMOS FET), wherein the first polysilicon structure serves as a first gate for the first NMOS FET, and wherein the first NMOS FET includes a first source situated over a p+ diffusion region within the common source region.

11. The IC cell of claim 10, wherein the second logic gate comprises:
a second PMOS FET, wherein the second polysilicon structure serves as a second gate for the second PMOS FET, and wherein the second PMOS FET shares the first source with the first PMOS FET; and
a second NMOS FET, wherein the second polysilicon structure serves as a second gate for the second NMOS FET, and wherein the second NMOS FET shares the first source with the first NMOS FET.

12. The IC cell of claim 11, further comprising:
a third polysilicon structure spaced apart and adjacent to the first polysilicon structure in the cell row direction; and
a fourth polysilicon structure spaced apart and adjacent to the second polysilicon structure in the cell row direction.

13. The IC cell of claim 12, wherein:
the first PMOS FET includes a first drain situated over the n+ diffusion region between the first and third polysilicon structures;
the first NMOS FET includes a first drain situated over the p+ diffusion region between the first and third polysilicon structures;
the second PMOS FET includes a second drain situated over the n+ diffusion region between the second and fourth polysilicon structures; and
the second NMOS FET includes a second drain situated over the p+ diffusion region between the second and fourth polysilicon structures.

14. The IC cell of claim 13, wherein:
the first logic gate includes a third pin on a second metal track situated between the first and third polysilicon structures; and
the second logic gate includes a fourth pin on a third metal track situated between the second and fourth polysilicon structures.

15. The IC cell of claim 14, wherein each adjacent pair of the first, second, third, and fourth polysilicon structures is separated by a first pitch, wherein each adjacent pair of the first, second, and third metal tracks is separated by a second pitch, and wherein a ratio of the first pitch to the second pitch is one (1).

16. The IC cell of claim 14, wherein the third and fourth pins comprise output pins, respectively.

17. The IC cell of claim 16, wherein the first and second polysilicon gate structures comprise cell terminating polysilicon gate structures.

18. The IC cell of claim 14, wherein:
the third pin is electrically coupled to the respective first drains of the first PMOS and NMOS FETs; and
the fourth pin is electrically coupled to the respective second drains of the second PMOS and NMOS FETs.

19. The IC cell of claim 14, wherein the third and fourth pins are situated between the n+ and p+ diffusion regions.

20. The IC cell of claim 14, wherein the third and fourth pins comprise input pins, respectively.

21. The IC cell of claim 20, further comprising:
a first intracell interconnect electrically coupling the third pin to the third polysilicon structure; and
a second intracell interconnect electrically coupling the fourth pin to the fourth polysilicon structure.

22. The IC cell of claim 21, wherein the first and second intracell interconnects are on an M0 metal layer.

23. The IC cell of claim 20, wherein the first logic gate comprises:
a third PMOS FET, wherein the third polysilicon structure serves as a third gate for the third PMOS FET, and wherein the third PMOS FET includes a third drain coupled to the first drain of the first PMOS FET; and
a third NMOS FET, wherein the third polysilicon structure serves as a third gate for the third NMOS FET, and wherein the third NMOS FET includes a third source coupled to the first drain of the first NMOS FET.

24. The IC cell of claim 23, wherein the second logic gate comprises:
a fourth PMOS FET, wherein the fourth polysilicon structure serves as a fourth gate for the fourth PMOS FET, and wherein the fourth PMOS FET includes a fourth drain coupled to the second drain of the second PMOS FET; and
a fourth NMOS FET, wherein the fourth polysilicon structure serves as a fourth gate for the fourth NMOS FET, and wherein the fourth NMOS FET includes a fourth source coupled to the second drain of the second NMOS FET.

25. The IC cell of claim 14, further comprising:
a fifth polysilicon structure spaced apart and adjacent to the third polysilicon structure in the cell row direction; and
a sixth polysilicon structure spaced apart and adjacent to the fourth polysilicon structure in the cell row direction.

26. The IC cell of claim 25, wherein:
the first logic gate includes a fifth pin on a fourth metal track situated between the third and fifth polysilicon structures; and
the second logic gate includes a sixth pin on a fifth metal track situated between the fourth and sixth polysilicon structures.

27. The IC cell of claim 26, wherein the fifth and sixth pins comprise output pins, respectively.

28. The IC cell of claim 25, wherein the fifth and sixth polysilicon structures are cell terminating polysilicon structures, respectively.

29. A method, comprising:
generating a first input logic signal;
generating a second input logic signal;
applying the first and second logic signals to first and second pins of an integrated circuit (IC) cell, wherein the IC cell includes:
a first logic gate comprising a first polysilicon structure and the first pin;
a second logic gate comprising a second polysilicon structure and the second pin, wherein the second polysilicon structure is spaced apart and adjacent to the first polysilicon structure in a cell row direction; and
a source region, common to the first and second logic gates, situated between the first and second polysilicon structures, wherein the first and second pins are on a first metal track directly over the common source region;
receiving a first output logic signal from the IC cell, wherein the first output logic signal is based on the first input logic signal; and
receiving a second output logic signal from the IC cell, wherein the second output logic signal is based on the second input logic signal.

30. A wireless communication device, comprising:
at least one antenna;
a transceiver coupled to the at least one antenna; and
an integrated circuit (IC) coupled to the transceiver, wherein the IC includes a set of one or more signal processing cores including an IC cell, comprising:
a first logic gate comprising a first polysilicon structure and a first pin;
a second logic gate comprising a second polysilicon structure and a second pin, wherein the second polysilicon structure is spaced apart and adjacent to the first polysilicon structure in a cell row direction; and
a source region, common to the first and second logic gates, situated between the first and second polysilicon structures, wherein the first and second pins are on a first metal track directly over the common source region.
